(19) United States
(12) Patent Application Publication
(10) Pub. No.: US 2026/0206137 A1
(43) Pub. Date: Jul. 16, 2026

(54) ELECTRONIC DEVICE AND MANUFACTURING METHOD THEREOF

(71) Applicant: InnoLux Corporation, Miao-Li County (TW)

(72) Inventors: Tzu-Kuan YANG, Miao-Li County (TW); Chia-Ping Tseng, Miao-Li County (TW); Chun-Chin FAN, Miao-Li County (TW); Chien-Ming CHEN, Miao-Li County (TW)

(73) Assignee: InnoLux Corporation, Miao-Li County (TW)

(21) Appl. No.: 19/393,542

(22) Filed: Nov. 18, 2025

Related U.S. Application Data
(60) Provisional application No. 63/734,762, filed on Dec. 17, 2024.

(30) Foreign Application Priority Data
Jul. 8, 2025 (CN) 202510933629.X

(51) Int. Cl. H05K 1/11; H05K 3/40; H10W 70/05; H10W 70/60; H10W 70/63

(52) U.S. Cl. CPC H05K 1/115; H05K 3/4076; H10W 70/095; H10W 70/611; H10W 70/635; H05K 2201/09563; H05K 2203/163

(57) ABSTRACT

A manufacturing method of an electronic device includes: providing a substrate; forming a through hole penetrating the substrate; providing a seed layer, the seed layer extending into the through hole; performing a first coating step to form a first coating on a surface of the seed layer, the first coating filling a portion of the through hole; and performing a second coating step to form a second coating on a portion of the surface of the seed layer, the second coating filling another portion of the through hole and connected to the first coating. A current density used in the first coating step is greater than a current density used in the second coating step.

### CROSS REFERENCE TO RELATED APPLICATION

This application claims the benefit of U.S. Provisional Application No. 63/734,762, filed on December 17^{th}, 2024. The content of the application is incorporated herein by reference.

### BACKGROUND OF THE DISCLOSURE

### 1. Field of the Disclosure

The present disclosure relates to an electronic device and a manufacturing method thereof, and more particularly to a manufacturing method of an electronic device including multiple coating steps and an electronic device manufactured by the method.

### 2. Description of the Prior Art

With the advancement of semiconductor packaging technologies, electronic products are increasingly being designed to be lighter, thinner, smaller, and to feature higher circuit density. A substrate structure that includes through holes formed in the substrate and filled with conductive materials for signal transmission has become one of the popular options in high-density interconnect packaging technologies. However, when forming conductive materials within the through holes of the substrate, the higher current density and easier metal deposition at the openings of the through holes often lead to premature closure at the openings. This results in incomplete filling of conductive material at the center of the through hole, forming holes that raise concerns regarding signal transmission and product reliability.

### SUMMARY OF THE DISCLOSURE

One of the objectives of the present disclosure is to provide a manufacturing method of an electronic device and an electronic device manufactured by the method. By performing coating steps in a stepwise manner during the manufacturing process to respectively form a first coating and a second coating for filling a through hole in a substrate, good through hole filling performance may be provided, so as to reduce the probability of forming voids or gaps within the through holes, as observed in conventional technologies, thereby improving the signal transmission quality and reliability of the electronic device.

An embodiment of the present disclosure provides a manufacturing method of an electronic device. The method includes: providing a substrate; forming a through hole penetrating the substrate; providing a seed layer, wherein the seed layer extends into the through hole; performing a first coating step to form a first coating on a surface of the seed layer, wherein the first coating fills a portion of the through hole; and performing a second coating step to form a second coating on a portion of the surface of the seed layer, wherein the second coating fills another portion of the through hole and is connected to the first coating. A current density used in the first coating step is greater than a current density used in the second coating step.

Another embodiment of the present disclosure provides an electronic device. The electronic device includes a substrate, a seed layer, a first coating and a second coating. The substrate includes a through hole penetrating the substrate. The seed layer is disposed on a side wall of the through hole. The first coating is disposed on a surface of the seed layer and fills a portion of the through hole. The second coating is disposed on a portion of the surface of the seed layer and fills another portion of the through hole, and the second coating is connected to the first coating. A grain size of the first coating is smaller than a grain size of the second coating.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a manufacturing method of an electronic device according to an embodiment of the present disclosure.

FIG. 2 to FIG. 5 are cross-sectional schematic diagrams illustrating a portion of the process of a manufacturing method of an electronic device according to an embodiment of the present disclosure.

FIG. 6 is a cross-sectional schematic diagram illustrating another embodiment of a portion of the process of a manufacturing method of an electronic device according to the present disclosure.

FIG. 7 is a partially enlarged cross-sectional schematic diagram of a region AR shown in FIG. 6.

FIG. 8 is a cross-sectional schematic diagram of an electronic device according to an embodiment of the present disclosure.

FIG. 9 is a partially enlarged cross-sectional schematic diagram of the electronic device shown in FIG. 8.

FIG. 10 is a cross-sectional schematic diagram of an electronic device according to another embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. The present disclosure does not intend to distinguish between components that differ in name but not function. In the following description and in the claims, the terms “include”, “comprise” and “have” are used in an open-ended fashion, and thus should be interpreted to mean “include, but not limited to...”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in the present disclosure, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” mentioned in the present disclosure generally mean being within 20% of a given value or range, or being within 10%, 5%, 3%, 2%, 1% or 0.5% of a given value or range.

In the present disclosure, the depth, thickness, width, and/or diameter may be measured by using an X-ray diffractometer (XRD), an optical microscope (OM), an electron microscope (such as a scanning electron microscope (SEM), a transmission electron microscope (TEM), etc.) or other methods, but not limited herein.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may applied to a high-speed computing module, a power module, a semiconductor package device, a display device, a light-emitting device, a backlight device, an antenna device, a sensing device, a tiled device or other suitable devices, but not limited herein. The electronic device may include electronic elements such as semiconductor elements. The semiconductor elements may include passive elements and active elements, such as capacitors, resistors, inductors, diodes, transistors, integrated circuits, etc. The diode may include a light emitting diode, a photodiode or a varicap diode. The semiconductor element may include a semiconductor layer or an electronic element manufactured by a semiconductor process, but not limited herein. The electronic device may include peripheral systems such as a driving system, a controlling system, a light source system, a shelving system, and the like. The outline of the electronic device may be a rectangle, a circle, a polygon, a shape with curved edge, curved or other suitable shapes. It should be noted that the electronic device of the present disclosure may be any combination of the above devices, but not limited herein.

The manufacturing method of the electronic device of the present disclosure may for example be applied to a wafer-level package (WLP) process or a panel-level package (PLP) process, wherein the WLP process or the PLP process may include a chip-first process or a chip-last process, but not limited herein. The electronic device may include the system on a chip (SoC), system in a package (SiP), antenna in package (AiP), co-packaged optics (CPO) or combinations of the above devices, but not limited herein.

It should be noted that the technical features in different embodiments described in the following can be replaced, recombined, or mixed with one another to constitute another embodiment without departing from the spirit of the present disclosure.

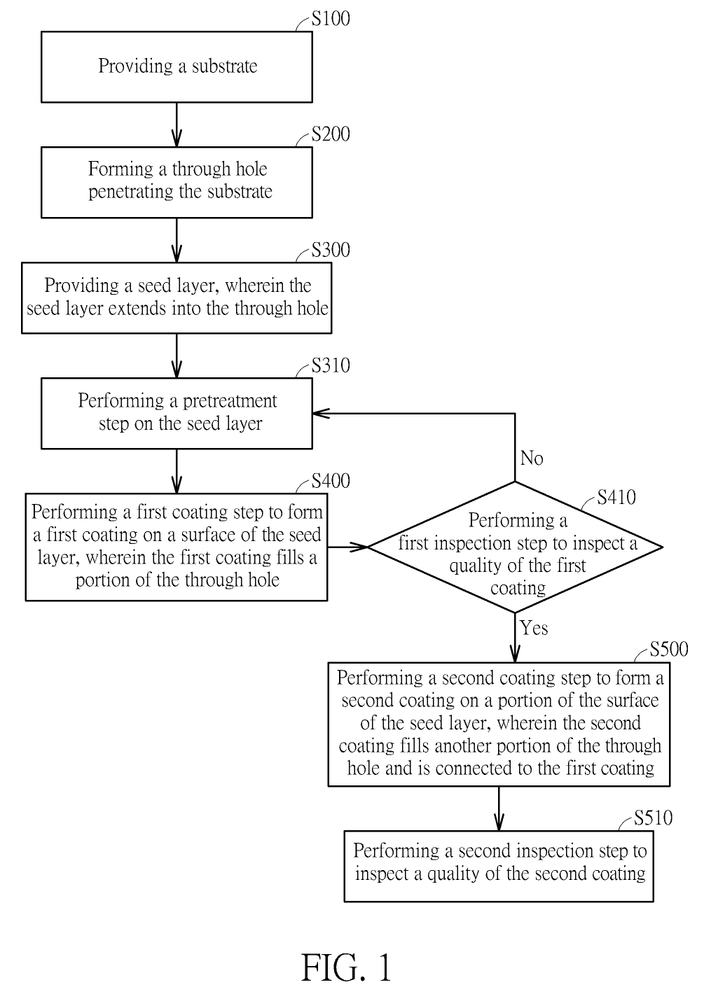

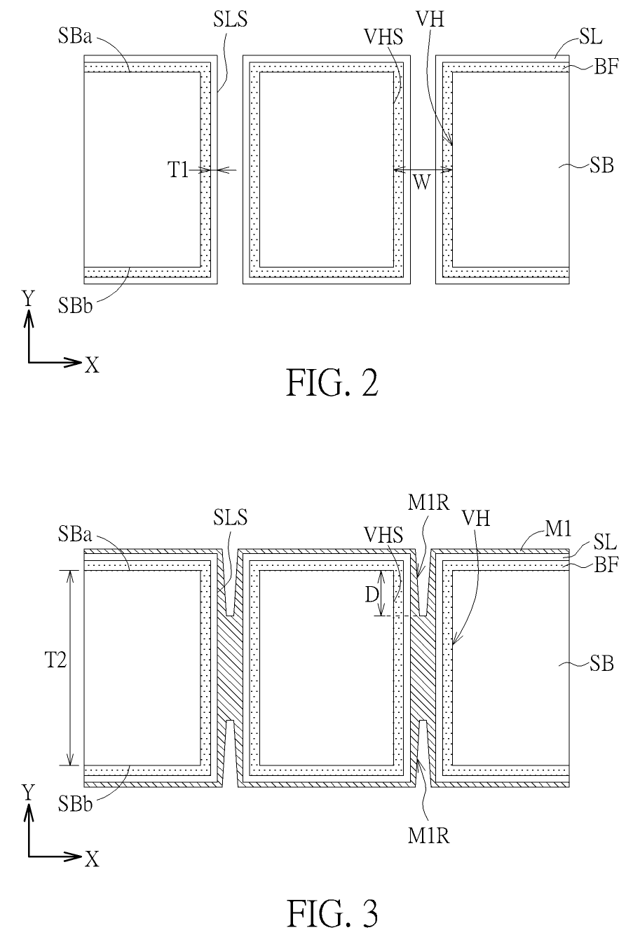

Please refer to FIG. 1 and FIG. 2 to FIG. 5. FIG. 1 is a flowchart of a manufacturing method of an electronic device according to an embodiment of the present disclosure. FIG. 2 to FIG. 5 are cross-sectional schematic diagrams illustrating a portion of the process of a manufacturing method of an electronic device according to an embodiment of the present disclosure. As shown in FIG. 1, a manufacturing method of an electronic device according to an embodiment of the present disclosure may include the following steps:

Step S100: providing a substrate;

Step S200: forming a through hole penetrating the substrate;

Step S300: providing a seed layer, wherein the seed layer extends into the through hole;

Step S400: performing a first coating step to form a first coating on a surface of the seed layer, wherein the first coating fills a portion of the through hole; and

Step S500: performing a second coating step to form a second coating on a portion of the surface of the seed layer, wherein the second coating fills another portion of the through hole and is connected to the first coating.

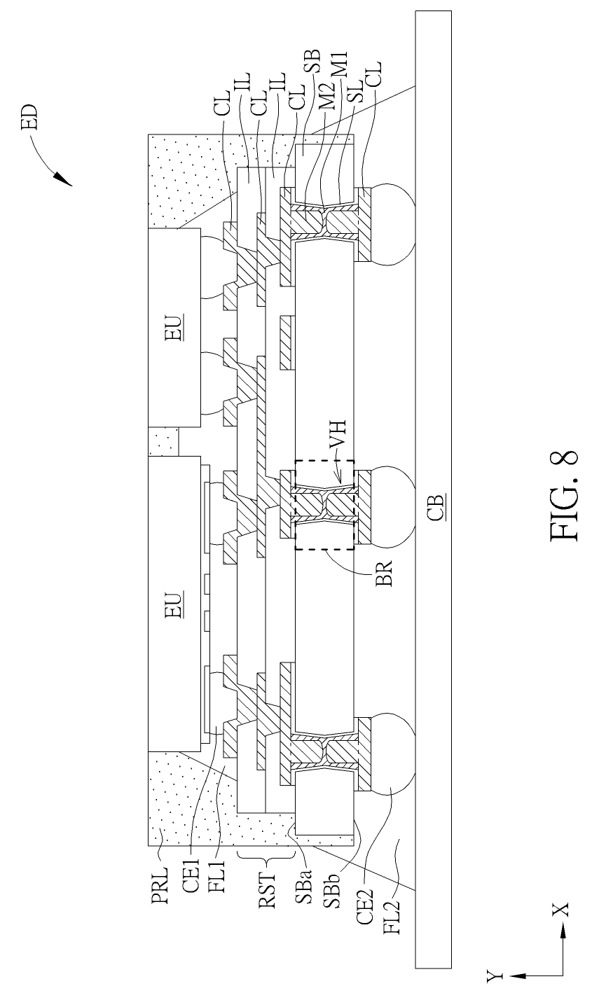

Specifically, as shown in FIG. 2, first, Step S100 may be performed to provide a substrate SB, wherein the substrate SB has an upper surface SBa and a lower surface SBb opposite to the upper surface SBa. The substrate SB may include a glass substrate, a transparent material including silicon, an optical layer, an acrylic board, a semiconductor structure substrate, combinations of the above or other transparent materials, and the substrate SB may have certain stiffness and insulation. That is to say, the stiffness of the substrate SB may be greater than the stiffness of a circuit structure (such as a redistribution structure RST shown in FIG. 8) formed on the substrate SB, for example, the stiffness of the substrate SB is greater than the stiffness of an insulating layer of the circuit structure, so that the warpage may be mitigated when the substrate SB is used for carrying the circuit structure, but not limited herein. The term “stiffness” referred to in the present disclosure may be tested by a universal testing machine (UTM). In some embodiments, the thermal expansion coefficient of the substrate SB may be greater than or equal to 1ppm/℃ and less than or equal to 10ppm/℃, thereby improving the support of the substrate SB or further improving the reliability of the electronic device. In some embodiments, the transmittance of the substrate SB for visible light may be at least greater than or equal to 80%.

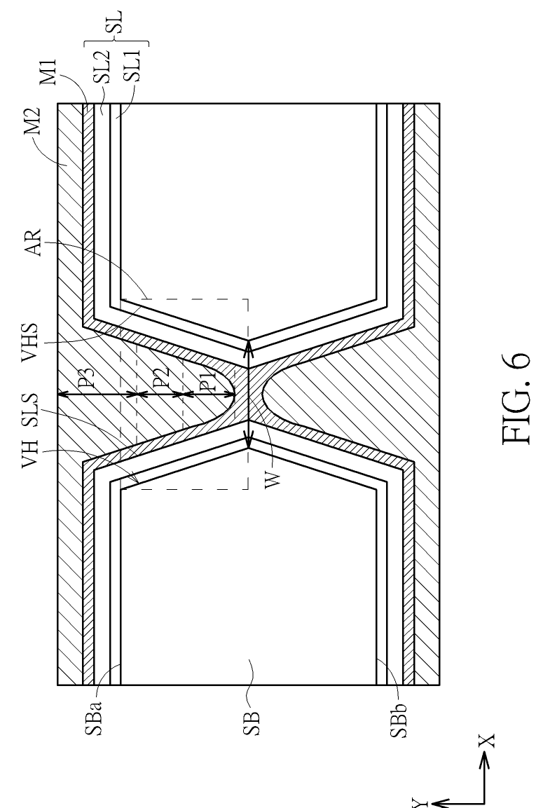

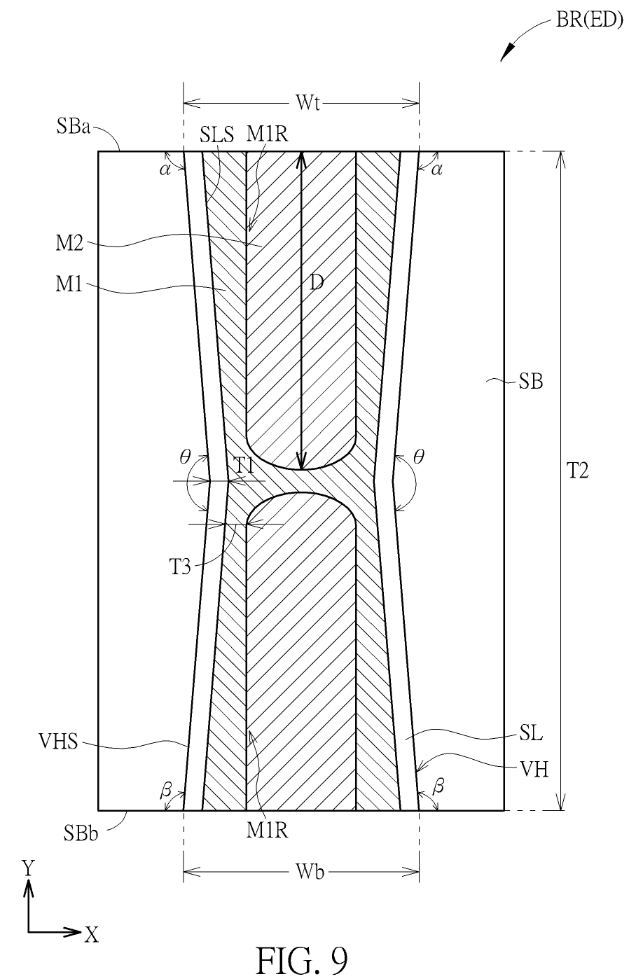

After Step S100, Step S200 may be performed to form a through hole VH penetrating the substrate SB, wherein a side wall VHS of the through hole VH is connected with the upper surface SBa and the lower surface SBb of the substrate SB. For example, one or more through holes VH may be formed in the substrate SB by performing a modification process and an etching process on the substrate SB. Specifically, a modification process (e.g., a laser modification process) may be performed on a portion of the substrate SB, wherein the portion of the substrate SB may correspond to a predetermined disposing position of the through hole VH. After the modification process, an etching process (e.g., a dry etching process or a wet etching process) may be selected to be performed on the substrate SB to remove the modified portion of the substrate SB, thereby forming one or more through holes VH penetrating the substrate SB. In some embodiments, in a cross-sectional view, the shape of the formed through hole VH may be a rectangle (as shown in FIG. 2 to FIG. 5), an hourglass shape (as shown in FIG. 6, FIG. 8 and FIG. 9), a trapezoid, an inverted trapezoid, or other suitable shapes.

After Step S200, Step S300 may be performed to provide a seed layer SL, wherein the seed layer SL extends into the through hole VH. The seed layer SL may facilitate the subsequent formation of a first coating M1 and a second coating M2, and/or enhance the adhesion between the layers. Specifically, the seed layer SL may be formed on the upper surface SBa and the lower surface SBb of the substrate SB, as well as on the side wall VHS of the through hole VH. The process for forming the seed layer SL may include, for example, atomic layer deposition (ALD), physical vapor deposition (PVD), chemical vapor deposition (CVD), sputtering, coating, other suitable deposition processes, or combinations thereof. The minimum thickness of the formed seed layer SL may be greater than or equal to 0.5 micrometers (µm). As shown in FIG. 2, the minimum thickness T1 of the seed layer SL at the center of the through hole VH may be greater than or equal to 0.5 micrometers, and the surface SLS of the seed layer SL is a continuous surface. That is, the seed layer SL is formed continuously and blanketly on the upper surface SBa and the lower surface SBb of the substrate SB and extends to the surface of the side wall VHS of the through hole VH. The term “center of the through hole VH” mentioned in the present disclosure may refer to a location at 40% to 60% depth of the through hole VH in a direction Y, where the through hole VH has a minimum diameter W (or minimum width) in a direction X. According to the embodiments of the present disclosure, the direction Y may be a normal direction of the substrate SB and parallel to a normal direction or a top-view direction of the upper surface SBa (or lower surface SBb) of the substrate SB, and the direction Y may be a normal direction of the manufactured electronic device. The direction X may be perpendicular to the direction Y and, for example, be a horizontal direction.

In some embodiments, the seed layer SL may be a single-layer structure (as shown in FIG. 2 and FIG. 9) or a multi-layer structure (as shown in FIG. 6, for example, formed of a first sub-layer SL1 and a second sub-layer SL2). The material of the seed layer SL may include, for example, titanium (Ti), titanium nitride (TiN), ruthenium (Ru), tantalum (Ta), silver (Ag), copper (Cu), or combinations thereof. In some embodiments, as shown in FIG. 2, before forming the seed layer SL (i.e., before Step S300), a buffer layer BF may optionally be formed on the substrate SB, such that the buffer layer BF covers the upper surface SBa and the lower surface SBb of the substrate SB as well as the side wall VHS of the through hole VH. Then, the seed layer SL is blanketly formed on the surface of the buffer layer BF. In some embodiments, as shown in FIG. 1, after forming the seed layer SL (i.e., after Step S300), Step S310 may be performed to carry out a pretreatment step on the seed layer SL. The pretreatment step may include surface treatment processes such as cleaning, micro-etching, etc., so as to enhance the bonding strength between the subsequent layer and the seed layer SL, but not limited herein.

As shown in FIG. 3, after forming the seed layer SL (i.e., after Step S300), Step S400 may be performed to carry out a first coating step to form a first coating M1 on the surface SLS of the seed layer SL, and the first coating M1 fills a portion of the through hole VH. A periodically varying current may be used in the first coating step, for example, using a periodic pulse reverse (PPR) current for electroplating, to form the first coating M1 on the seed layer SL. According to the embodiment shown in FIG. 3, the first coating M1 may fill a portion of the through hole VH and fully occupy the central region of the through hole VH, thereby forming a bridge-like structure such that the upper surface SBa and the lower surface SBb of the substrate SB are no longer connected through the through hole VH. Specifically, the first coating M1 may be recessed respectively from the upper surface SBa and the lower surface SBb within the through hole VH, thereby forming two recesses M1R. That is to say, the first coating M1 may have two recesses M1R respectively located on opposite sides of the first coating M1 in the direction Y. In the cross-sectional view shown in FIG. 3, the substrate SB may have a thickness T2 in the direction Y, and a depth D of each recess M1R may be greater than or equal to one-fourth of the thickness T2 and less than or equal to one-half of the thickness T2 (i.e., T2*1/4≤D≤T2*1/2). The depth D of the recess M1R may be obtained by measuring the maximum distance from the upper surface SBa or lower surface SBb of the substrate SB to the surface of the first coating M1 along the direction Y.

In some embodiments, as shown in FIG. 1, after performing the first coating step to form the first coating M1 (i.e., after Step S400), Step S410 may be performed to carry out a first inspection step to inspect a quality of the first coating M1. Specifically, the first inspection step may be performed using inspection equipment to determine, for example, whether the first coating M1 forms a bridge structure and/or whether the depth D of the recess M1R is greater than or equal to one-fourth of the thickness T2 and less than or equal to one-half of the thickness T2, thereby determining whether the quality of the first coating M1 meets the required standard. When it is determined that the quality of the first coating M1 does not meet the standard based on the inspection result of the first inspection step, for example, when the depth D of the recess M1R is less than one-fourth of the thickness T2 or greater than one-half of the thickness T2, then Step S310 and Step S400 may be performed again, i.e., the pretreatment step and the first coating step may be repeated to improve the formation of the first coating M1. When it is determined that the quality of the first coating M1 meets the standard based on the inspection result of the first inspection step, for example, when the depth D of the recess M1R is greater than or equal to one-fourth of the thickness T2 and less than or equal to one-half of the thickness T2, then Step S500 may be performed.

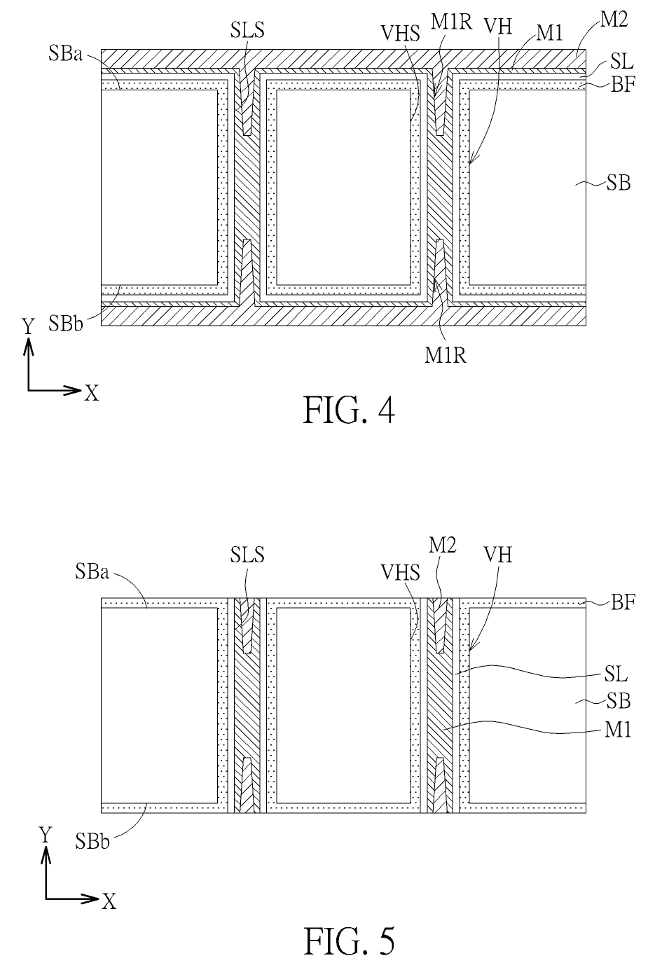

As shown in FIG. 4, after forming the first coating M1 (i.e., after Step S400), Step S500 may be performed to carry out a second coating step to form a second coating M2 on a portion of the surface SLS of the seed layer SL, and the second coating M2 fills another portion of the through hole VH and is connected to the first coating M1, wherein the current density used in the first coating step is greater than the current density used in the second coating step. A direct current (DC) may be used in the second coating step, and the coating time of the first coating step may be greater than the coating time of the second coating step, so as to form the second coating M2 on the first coating M1. According to the embodiment shown in FIG. 4, the second coating M2 may fill the two recesses M1R located on opposite sides of the first coating M1, thereby filling the remaining portion of the through hole VH that is not filled by the first coating M1. Since a portion of the through hole VH has already been filled by the first coating M1, the second coating M2 is disposed corresponding to only a portion of the surface SLS of the seed layer SL. That is to say, as shown in FIG. 4, within the through hole VH, a portion of the surface SLS of the seed layer SL may be overlapped with the first coating M1, the recesses M1R and the second coating M2 in the direction X, while another portion of the surface SLS of the seed layer SL may be overlapped only with the first coating M1 in the direction X and not overlapped with the second coating M2. According to the embodiments of the present disclosure, the grain size of the formed first coating M1 may be smaller than the grain size of the formed second coating M2. The materials of the first coating M1 and the second coating M2 may be similar with the conductive layer CL. By performing coating steps in a stepwise manner during the manufacturing process to respectively form the first coating M1 and the second coating M2 for filling the through hole VH, and by using different current densities and current types in the first coating step and the second coating step, good through hole filling performance may be provided, so that the probability of forming unfilled voids or gaps within the through hole VH during the coating process may be reduced. Furthermore, the grain size of the first coating M1 formed adjacent to the center of the through hole VH is smaller, so that the stress caused by the mismatch in thermal expansion coefficients of materials between the substrate SB and the first coating M1 may be reduced. Based on the above, the manufacturing method of the present disclosure may improve the signal transmission quality and reliability of the manufactured electronic device.

In some embodiments, as shown in FIG. 1, after performing the second coating step to form the second coating M2 (i.e., after Step S500), Step S510 may be performed to carry out a second inspection step to inspect a quality of the second coating M2. Specifically, the second inspection step may be performed using inspection equipment to determine whether the quality of the second coating M2 meets the required standard, for example, by confirming whether the thickness of the second coating M2 meets specifications and/or by using optical instruments to determine whether the porosity of the second coating M2 is less than or equal to 3 vol%, thereby determining whether to proceed with subsequent steps, such as forming a redistribution structure RST on the second coating M2 as shown in FIG. 8. When it is determined that the quality of the second coating M2 does not meet the standard based on the inspection result of the second inspection step, the coating step may be performed again to improve the formation of the second coating M2. When it is determined that the quality of the second coating M2 meets the standard based on the inspection result of the second inspection step, the subsequent steps may be continued. In some embodiments, as shown in FIG. 5, before forming the redistribution structure RST (as shown in FIG. 8), a portion of the seed layer SL, a portion of the first coating M1 and a portion of the second coating M2 may be removed to expose the buffer layer BF located on the upper surface SBa and the lower surface SBb of the substrate SB. For example, the portion of the seed layer SL, the portion of the first coating M1 and the portion of the second coating M2 may be removed by a chemical mechanical polishing process and/or a wet etching process, but not limited herein.

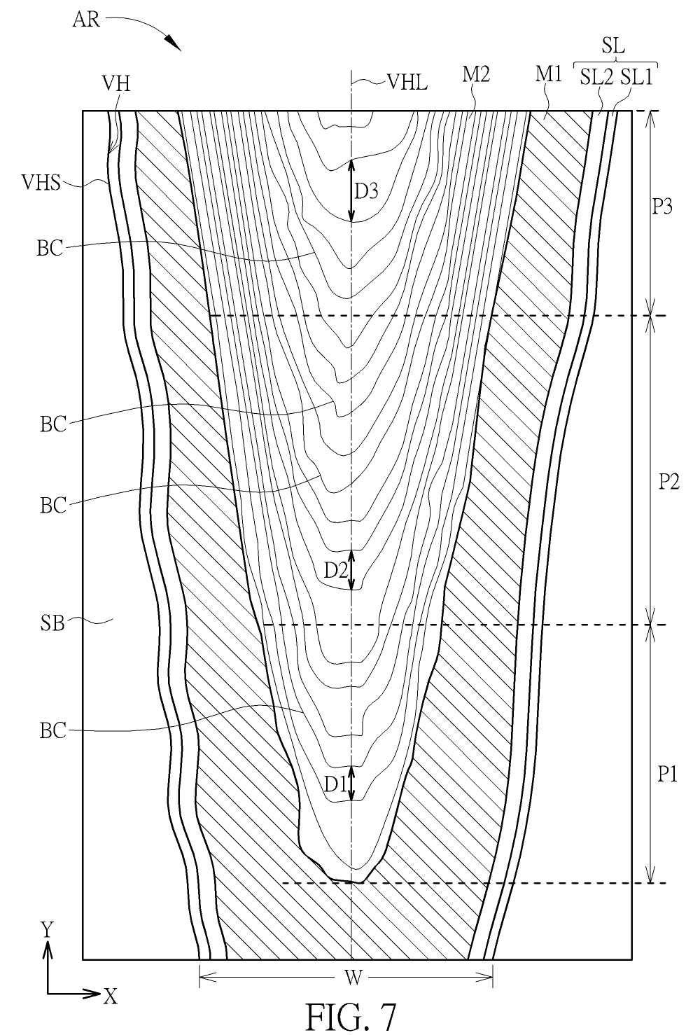

Please refer to FIG. 6 and FIG. 7. FIG. 6 is a cross-sectional schematic diagram illustrating another embodiment of a portion of the process of a manufacturing method of an electronic device according to the present disclosure, wherein the process step shown in FIG. 6 may be another embodiment of the process step shown in FIG. 4. FIG. 7 is a partially enlarged cross-sectional schematic diagram of a region AR shown in FIG. 6. The cross-sectional view shown in FIG. 7 may be obtained, for example, by using an optical microscope, focused ion beam (FIB) technology, electron backscatter diffraction (EBSD) technology, a metallographic microscope or an X-ray diffractometer, wherein a plurality of grain boundary profiles BC shown in FIG. 7 may be formed through an etching process. The partial process step of the electronic device shown in FIG. 6 is different from the embodiment shown in FIG. 4 in that the through hole VH may have an hourglass shape, the buffer layer BF may not be disposed on the substrate SB, and the seed layer SL may be a multi-layer structure formed of a first sub-layer SL1 and a second sub-layer SL2. Specifically, the first sub-layer SL1 may first be formed on the upper surface SBa and the lower surface SBb of the substrate SB, as well as on the side wall VHS of the through hole VH, and then the second sub-layer SL2 may be formed on the first sub-layer SL1 and extend into the through hole VH, such that the first sub-layer SL1 and the second sub-layer SL2 are sequentially formed on the upper surface SBa and the lower surface SBb of the substrate SB and on the side wall VHS of the through hole VH. The material of the first sub-layer SL1 may include, for example, titanium (Ti), titanium nitride (TiN), ruthenium (Ru), tantalum (Ta), silver (Ag) or combinations thereof. The first sub-layer SL1 may help enhance the bonding strength between metal material and inorganic material, i.e., improve the adhesion between layers, and the first sub-layer SL1 may further serve as a barrier layer to inhibit electron migration. The material of the second sub-layer SL2 may include, for example, copper (Cu), and the second sub-layer SL2 may facilitate the formation of the first coating M1 thereon.

According to the embodiment shown in FIG. 6 and FIG. 7, the second coating step for forming the second coating M2 may include a plurality of sub-steps, and different current densities are used in any two of the plurality of sub-steps. The plurality of sub-steps may include a first sub-step and a second sub-step. In some embodiments, the plurality of sub-steps may further include a third sub-step or more sub-steps. In this embodiment, the plurality of sub-steps include the first sub-step, the second sub-step and the third sub-step as an example, but not limited herein. The number of sub-steps included in the second coating step may be greater or fewer. Specifically, during the second coating step (i.e., Step S500), the first sub-step may be performed to form a first portion P1 of the second coating M2, then the second sub-step may be performed to form a second portion P2 of the second coating M2, and then the third sub-step may be performed to form a third portion P3 of the second coating M2. In the direction Y, the first portion P1 may be located between the first coating M1 and the second portion P2, and the second portion P2 may be located between the first portion P1 and the third portion P3. Similar layer stacking structures may be formed along the direction Y from the center of the through hole VH to the upper surface SBa and the lower surface SBb of the substrate SB. In this embodiment, a direct current (DC) may be used in each sub-step of the second coating step, wherein the current density used in the second sub-step is greater than the current density used in the first sub-step, the current density used in the third sub-step is greater than the current density used in the second sub-step, and the current density used in the first coating step for forming the first coating M1 is greater than the current density used in the third sub-step. Furthermore, the coating time of the first coating step may be greater than the coating time of the first sub-step, the coating time of the first sub-step may be greater than the coating time of the second sub-step, and the coating time of the second sub-step may be greater than the coating time of the third sub-step. For example, the current density used in the first sub-step may be 5 amperes per square foot (ASF) with a coating time of 120 minutes, the current density used in the second sub-step may be 10 ASF with a coating time of 60 minutes, and the current density used in the third sub-step may be 20 ASF with a coating time of 30 minutes, but the present disclosure is not limited herein.

As shown in FIG. 7, the first coating M1 and the first portion P1, the second portion P2 and the third portion P3 of the second coating M2 that are formed may have different crystallization densities, grain sizes, and/or crystal orientations. Specifically, the grain size of the first coating M1 may be smaller than the grain size of the first portion P1, the grain size of the first portion P1 may be smaller than the grain size of the second portion P2, and the grain size of the second portion P2 may be smaller than the grain size of the third portion P3. The relationship of grain sizes of the above portions may be compared based on the average grain diameter in the region adjacent to a center line VHL of the through hole VH, wherein the center line VHL of the through hole VH may be parallel to the direction Y and pass through the geometric center of the through hole VH. In the cross-sectional view shown in FIG. 7, along the center line VHL of the through hole VH and in the direction Y, a first spacing D1 exists between two adjacent grain boundary profiles BC of the first portion P1, a second spacing D2 exists between two adjacent grain boundary profiles BC of the second portion P2, and a third spacing D3 exists between two adjacent grain boundary profiles BC of the third portion P3, wherein the first spacing D1 may be less than the second spacing D2, and the second spacing D2 may be less than the third spacing D3. For example, the first spacing D1 may be 7.5 micrometers, the second spacing D2 may be 8.6 micrometers, and the third spacing D3 may be 10 micrometers, but not limited herein. In some embodiments, a ratio of the first spacing D1 to the minimum diameter W (also referred to as the waist diameter) of the through hole VH may be greater than or equal to 0.08 and less than or equal to 0.13 (i.e., 0.08≤D1/W≤0.13), a ratio of the second spacing D2 to the minimum diameter W of the through hole VH may be greater than or equal to 0.07 and less than or equal to 0.12 (i.e., 0.07≤D2/W≤0.12), and a ratio of the third spacing D3 to the minimum diameter W of the through hole VH may be greater than or equal to 0.06 and less than or equal to 0.11 (i.e., 0.06≤D3/W≤0.11). According to some embodiments, the first coating M1 may also include a plurality of grain boundary profiles (not shown), and a ratio of a spacing DM1 between two adjacent grain boundary profiles of the first coating M1 to the minimum diameter W of the through hole VH may be greater than or equal to 0.02 and less than or equal to 0.06 (i.e., 0.02≤DM1/W≤0.06), wherein this ratio (i.e., DM1/W) is less than the ratios of the spacings between adjacent grain boundary profiles BC in each portion of the second coating M2 to the minimum diameter W of the through hole VH. As shown in FIG. 6, the closer to the center of the through hole VH, the smaller the diameter of the through hole VH, and thus forming smaller and denser grains near the center of the through hole VH may help reduce stress generation. In contrast, the closer to the upper surface SBa and the lower surface SBb of the substrate SB, the larger the diameter of the through hole VH, and thus larger and less dense grains may be formed to reduce process time. In some embodiments, when forming the portions of the second coating M2 near the upper surface SBa and the lower surface SBb of the substrate SB, a plating solution formulation and plating conditions with better filling rates may be used to accelerate the filling of the through hole VH and reduce overall process time. For example, the plating solution may include copper sulfate (CuSO₄·5H₂O), sulfuric acid (H₂SO₄), chloride ions (Cl⁻), bis-(sodium sulfopropyl) disulfide, 3-mercapto-1-propanesulfonic acid sodium salt, leveling agent, buffer agent, inhibitors, stabilizers, or any combinations thereof. The leveling agent may help flatten the coating and reduce surface roughness. The buffer agent is used to stabilize the pH value of the electroplating solution, thereby preventing drastic changes in pH value during the electroplating process. The inhibitor is used to inhibit the occurrence of certain chemical reactions, such as the formation of copper particles, thereby preventing issues with the plating layer. The stabilizer is used to maintain the stability of the electroplating solution. Accordingly, an appropriate plating solution formulation and plating conditions may be adjusted to form the coating or the desired conductive layer.

According to the manufacturing method illustrated in FIG. 6 and FIG. 7, the second coating step may include multiple sub-steps to respectively form different portions of the second coating M2 (e.g., a first portion P1, a second portion P2 and a third portion P3). Furthermore, along the direction Y, from a region near the center of the through hole VH to the upper surface SBa (or the lower surface SBb) of the substrate SB, the corresponding sub-steps used to form the respective portions of the second coating M2 may be performed with increasing current density and decreasing electroplating time. By changing the current density and electroplating time in each sub-step of the second coating step, the volume ratio, crystallization density, grain size, and/or crystal orientation of each partial region may be adjusted. This may reduce the probability of forming unfilled voids within the through hole VH during coating, and may alleviate stress caused by mismatches in the thermal expansion coefficients of materials between the substrate SB and the first coating M1 and the second coating M2, thereby reducing the risk of substrate SB cracking and improving the reliability of the manufactured electronic device.

Please refer to FIG. 8 and FIG. 9. FIG. 8 is a cross-sectional schematic diagram of an electronic device according to an embodiment of the present disclosure. FIG. 9 is a partially enlarged cross-sectional schematic diagram of the electronic device shown in FIG. 8, wherein FIG. 9 is an enlarged schematic diagram of a region BR shown in FIG. 8. The electronic device ED shown in FIG. 8 is merely an example, and the structure of the electronic device of the present disclosure is not limited thereto. In some embodiments, the manufacturing process for the region BR in the electronic device ED shown in FIG. 8 may be implemented according to the manufacturing method illustrated in FIG. 2 to FIG. 5 or the manufacturing method shown in FIG. 6 and FIG. 7, and the through holes VH and the layer stacking structure therein of the electronic device ED may refer to the embodiments shown in FIG. 5 or FIG. 6. As shown in FIG. 8 and FIG. 9, an electronic device ED manufactured by the manufacturing method of the present disclosure includes a substrate SB, a seed layer SL, a first coating M1 and a second coating M2, and the electronic device ED may further include a redistribution structure RST disposed on one side of the substrate SB. The substrate SB includes one or more through holes VH, and each through hole VH penetrates the substrate SB. The seed layer SL is disposed on the side wall VHS of the through hole VH, wherein the side wall VHS of the through hole VH may be connected with the upper surface SBa and the lower surface SBb of the substrate SB. The first coating M1 is disposed on the surface SLS of the seed layer SL and fills a portion of the through hole VH. The second coating M2 is disposed on a portion of the surface SLS of the seed layer SL and fills another portion of the through hole VH, and the second coating M2 is connected to the first coating M1. The grain size of the first coating M1 is smaller than the grain size of the second coating M2. The detailed structures and materials of the layers and components of the electronic device ED described above may refer to the aforementioned embodiments, which will not be redundantly described herein.

In the cross-sectional view of the electronic device ED shown in FIG. 9, the substrate SB may have a thickness T2 in the direction Y. The first coating M1 may include two recesses M1R respectively located on opposite sides of the first coating M1 in the direction Y, and a depth D of each recess M1R may be greater than or equal to one-fourth of the thickness T2 and less than or equal to one-half of the thickness T2. That is to say, in the direction Y, the distance between the connection portion of the first coating M1 within the through hole VH and the upper surface SBa of the substrate SB may be greater than or equal to one-fourth of the thickness T2 and less than or equal to one-half of the thickness T2, thereby reducing the probability of forming voids within the through hole VH. The thickness T2 of the substrate SB may range from 0.2 millimeters (mm) to 1.8 millimeters, but not limited herein. In the direction X, a top diameter Wt and a bottom diameter Wb of the through hole VH may each range from 30 micrometers to 100 micrometers, but not limited herein. An included angle α may exist between the side wall VHS of the through hole VH and the upper surface SBa of the substrate SB, and an included angle β may exist between the side wall VHS of the through hole VH and the lower surface SBb of the substrate SB, wherein the included angle α and/or the included angle β may be greater than or equal to 90 degrees and less than or equal to 100 degrees (i.e., 90°≤α≤100° and/or 90°≤β≤100°). In some embodiments, the through hole VH may have a hourglass shape, and an included angle θ exist between the side walls VHS on the upper and lower sides of the center of the through hole VH, wherein the included angle θ may be greater than 90 degrees and less than 180 degrees (i.e., 90°<θ<180°). In other embodiments, the through hole VH may have a rectangular shape, wherein the included angle θ may be equal to 180 degrees, but not limited herein.

In some embodiments, as shown in FIG. 9, in the direction X, the minimum thickness T1 of the seed layer SL may be greater than or equal to 0.5 micrometers, i.e., the minimum thickness T1 of the seed layer SL at the center of the through hole VH may be greater than or equal to 0.5 micrometer, and the minimum thickness T3 of the first coating M1 may be greater than 0.5 micrometers, but not limited herein. The volume ratio of the second coating M2 in the through hole VH may be greater than or equal to 11% and less than or equal to 87%, i.e., the second coating M2 disposed within the through hole VH may occupy 11% to 87% of the accommodation space of the through hole VH, thereby mitigating stress and reducing the risk of substrate SB fracture.

According to the embodiment shown in FIG. 8, the redistribution structure RST may be disposed on the substrate SB, and the redistribution structure RST may include at least one conductive layer (e.g., one or more conductive layers CL) and at least one insulating layer (e.g., one or more insulating layers IL). Each insulating layer IL may include at least one through-via, such that the first coating M1 and the second coating M2 within the through hole VH of the substrate SB are electrically connected to the conductive layers CL in the stacking direction, wherein the stacking direction as referred to in the present disclosure may be the direction Y. In some embodiments, the conductive layers CL closest to the substrate SB and located on opposite sides of the second coating M2 in the direction Y may be formed together with the second coating M2 in the same process step or they may be formed in different process steps, thereby forming conductive elements. For example, referring to FIG. 5, after removing a portion of the second coating M2, the conductive layers CL may be further provided by a suitable process. The conductive layer CL farthest from the substrate SB may include a plurality of connection pads for bonding with an electronic unit EU or other suitable components. One or more electronic units EU may be disposed on the redistribution structure RST and bonded to the redistribution structure RST through bonding elements CE1, such that the electronic unit EU may be electrically connected to other components through the conductive layers CL and the first coating M1 and the second coating M2 in the through holes VH of the substrate SB. For example, the electronic unit EU may be further electrically connected to a circuit board CB through bonding elements CE2 disposed on one side of the substrate SB opposite to the redistribution structure RST. The bonding elements CE1 and the bonding elements CE2 may include, for example, solder balls, nickel, gold, copper, gallium or other suitable conductive materials. The insulating layer IL may include, for example, polyimide (PI), photosensitive polyimide (PSPI), Ajinomoto build-up film (ABF), silicon oxide (SiOx), silicon nitride (SiNx), silicon oxide nitride (SiOxNy) or other suitable dielectric materials. The conductive layer CL may include conductive material, including, for example, copper (Cu), titanium (Ti), aluminum (Al), molybdenum (Mo), nickel (Ni), ruthenium (Ru), tantalum (Ta), tungsten (W), nitride, carbide, other conductive materials or any combination of the above, but not limited herein.

As shown in FIG. 8, the electronic device ED may further include a protective layer PRL surrounding the substrate SB, the redistribution structure RST and the electronic units EU, so as to isolate moisture and air and/or reduce the damage to the electronic unit EU. The protective layer PRL may include, organic resin, epoxy, epoxy molding compound (EMC), ceramics, poly(methyl methacrylate) (PMMA), polydimethylsiloxane (PDMS), other suitable materials or combinations of the above materials, but not limited herein. In some embodiments, the electronic device ED may further include a filling layer FL1 and a filling layer FL2. The filling layer FL1 may be disposed between the electronic unit(s) EU and the redistribution structure RST to surround and protect the bonding elements CE1, and the filling layer FL2 may be disposed between the substrate SB and the circuit board CB to surround and protect the bonding elements CE2 and may be used as a buffer layer, but not limited herein.

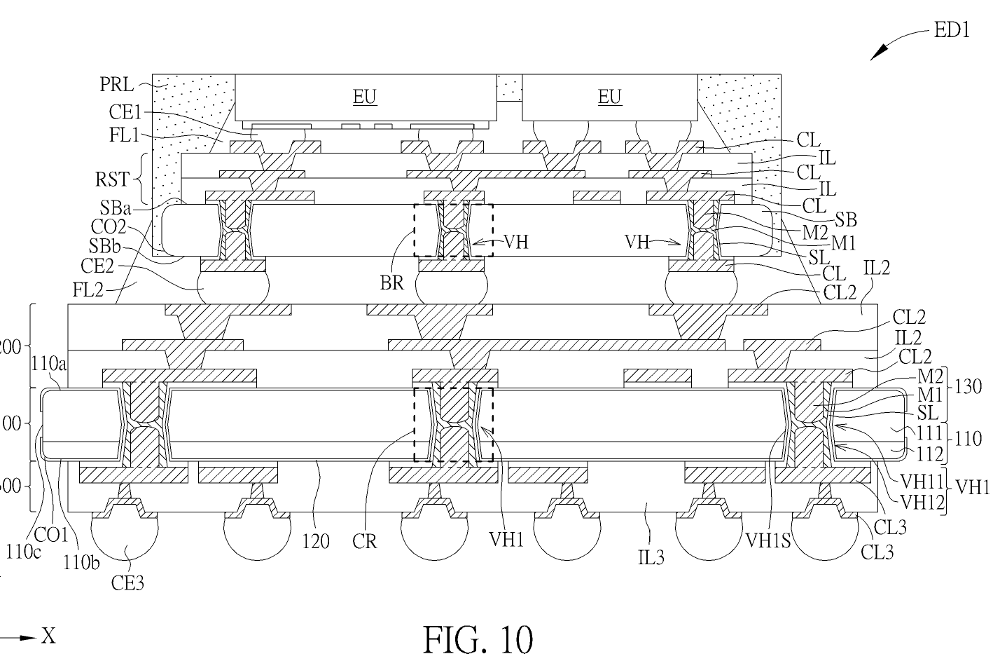

Please refer to FIG. 10, which is a cross-sectional schematic diagram of an electronic device according to another embodiment of the present disclosure. As shown in FIG. 10, an electronic device ED1 of this embodiment is different from the electronic device ED shown in FIG. 8 in that the circuit board CB may include a core substrate 100, a circuit structure 200 and a circuit structure 300, wherein the circuit structure 200 and the circuit structure 300 are respectively disposed on the upper side and the lower side of the core substrate 100. The core substrate 100 may include a substrate 110, a buffer layer 120 and a plurality of conductive elements 130. The substrate 110 may include a sub-substrate 111 and a sub-substrate 112 stacked in sequence, wherein the substrate 110 may have a plurality of through holes VH1, and each through hole VH1 may be formed by a sub-through hole VH11 in the sub-substrate 111 and a sub-through hole VH12 in the sub-substrate 112. In some embodiments, the substrate 110 may include a structure composed of more than two layers of sub-substrates stacked in sequence. The thermal expansion coefficients and thickness between any two of the sub-substrates may be the same or different. For example, the thermal expansion coefficient of the sub-substrate 111 may be different from that of the sub-substrate 112, such as the thermal expansion coefficient of the sub-substrate 111 being less than that of the sub-substrate 112. The thickness of the substrate 110 may be greater than the thickness of the substrate SB. The material of the substrate 110 in this embodiment may be similar or identical to the material of the substrate SB, which will not be redundantly described herein. In some embodiments, the light transmittance of the substrate 110 may be different from that of the substrate SB. For example, the light transmittance of the substrate 110 for white light may be higher than that of the substrate SB. In some embodiments, the corners CO1 of the substrate 110 and the corners CO2 of the substrate SB may respectively have curved corners, wherein the radius of curvature of the corner CO2 of the substrate SB may be greater than that of the corner CO1 of the substrate 110.

The buffer layer 120 may be used, for example, to provide buffering and protection for the substrate 110. The buffer layer 120 may at least cover the corners of the substrate 110 to reduce the risk of cracking at the corners of the substrate 110. For example, the buffer layer 120 may cover the corners formed by the connection between the side wall VH1S of the through hole VH1 and the upper surface 110a of the substrate 110, or the corners formed by the connection between the side wall VH1S of the through hole VH1 and the lower surface 110b of the substrate 110. In this embodiment, the buffer layer 120 may cover, for example, the upper surface 110a, the lower surface 110b and the side surface 110c of the substrate 110, and the side wall VH1S of the through hole VH1, wherein the buffer layer 120 may cover the joint between the sub-substrate 111 and the sub-substrate 112 on the side surface 110c, but not limited herein. The buffer layer 120 may also serve as an adhesion promoter layer, used to enhance the bonding strength between the substrate 110 and the seed layer SL, or the buffer layer 120 may be other suitable layers. The method for forming the buffer layer 120 may include a deposition process, a coating process combined with the laser drilling process or etching process, or other suitable processes. The deposition process may include, for example, atomic layer deposition, physical deposition, or chemical deposition. The thickness of the buffer layer 120 may be, for example, greater than or equal to 0.25 micrometers. In some embodiments, the buffer layer 120 may not be formed after the step of providing the substrate 110.

The buffer layer 120 may include, for example, inorganic materials or organic materials. The inorganic materials of the buffer layer 120 may include, for example, metals, metal alloys, oxides, nitrides, suitable ceramic materials, other suitable inorganic materials, or combinations thereof, but not limited herein. The organic materials of the buffer layer 120 may include, for example, polyimide (PI), poly-p-xylylene (also known as parylene), benzocyclobutene (BCB), epoxy, polycarbonate (PC), polyethylene terephthalate (PET), polyethylene naphthalate (PEN), polymers, or other suitable materials. The buffer layer 120 may be a single-layer or multi-layer structure. When the buffer layer 120 is a multi-layer structure, the buffer layer 120 may include for example, a structure of sequentially stacked inorganic material layer, organic material layer, and inorganic material layer; a structure of sequentially stacked organic material layer, inorganic material layer, and organic material layer; a structure of sequentially stacked organic material layer, organic material layer, and organic material layer; or other suitable configurations. The toughness of the buffer layer 120 may be, for example, greater than or equal to 0.1 kilojoules per square meter (kJ/m²) and less than or equal to 100 kJ/m² (i.e., 0.1 kJ/m²≤ toughness of the buffer layer 120≤100 kJ/m²). In the present disclosure, the toughness of a layer may be determined by integrating the area under the stress-strain curve, and the stress-strain curve may be obtained by performing a tensile test on the layer using a universal testing machine. The dissipation factor of the buffer layer 120 may be less than the dissipation factor of the substrate 110. For example, under an operating frequency greater than or equal to 10 megahertz (MHz), the dissipation factor of the buffer layer 120 may be less than 0.1, thereby reducing the impact on signal transmission, particularly effectively minimizing the influence on high-frequency signal transmission.

According to the embodiment shown in FIG. 10, the manufacturing process for a region CR in the electronic device ED1 may be implemented according to the manufacturing method illustrated in FIG. 2 to FIG. 5 or the manufacturing method illustrated in FIG. 6 and FIG. 7, and the through holes VH1 and the layer stacking structure therein of the electronic device ED1 may refer to the through holes VH shown in FIG. 5, FIG. 6, FIG. 8, or FIG. 9. That is to say, a seed layer SL, a first coating M1 and a second coating M2 may be disposed in each of the through holes VH1 to form a plurality of conductive elements 130. For example, in the manufacturing process of the electronic device ED1, after the step of forming the buffer layer 120 (or the step of providing the substrate 110), the seed layer SL may be formed on the buffer layer 120 (or the substrate 110), and the seed layer SL extends into the through hole VH1 to facilitate the subsequent formation of the first coating M1. The seed layer SL may, for example, cover the buffer layer 120 located on the upper surface 110a and the lower surface 110b of the substrate 110 and the side wall VH1S of the through hole VH1, but not limited herein. In some embodiments, when the buffer layer 120 is not formed on the substrate 110, the seed layer SL may be directly formed on the upper surface 110a and the lower surface 110b of the substrate 110 and the side wall VH1S of the through hole VH1. The thickness of the seed layer SL may be, for example, greater than or equal to 0.1 micrometers, wherein the thickness of the seed layer SL mentioned above may be the maximum thickness thereof.

As shown in FIG. 10, the circuit structure 200 may include at least one conductive layer CL2 and at least one insulating layer IL2, and the circuit structure 300 may include at least one conductive layer CL3 and at least one insulating layer IL3. The topmost conductive layer CL2 in the circuit structure 200 may be electrically connected to the bonding elements CE2. Each insulating layer IL2 and each insulating layer IL3 may include at least one through-via, such that the first coating M1 and the second coating M2 within the through hole VH1 of the substrate 110 are electrically connected to the conductive layers CL2 and CL3 in the stacking direction Y. In some embodiments, the conductive layers CL2 and CL3 closest to the substrate 110 and located on opposite sides of the second coating M2 in the direction Y may be formed together with the second coating M2 in the same process step or they may be formed in different process steps. The conductive layer CL3 farthest from the substrate 110 in the circuit structure 300 may include a plurality of connection pads, and the electronic device ED1 may further include a plurality of bonding elements CE3 disposed on one side of the connection pads opposite to the substrate 110, for bonding with other components. The materials of the conductive layers CL2 and CL3 may refer to the materials of the conductive layer CL described in the aforementioned embodiments, the materials of the insulating layers IL2 and IL3 may refer to the materials of the insulating layer IL described in the aforementioned embodiments, and the material of the bonding elements CE3 may refer to the material of the bonding elements CE1 and CE2 described in the aforementioned embodiments, which will not be redundantly described herein.

From the above description, according to the manufacturing method of the electronic device in the embodiments of the present disclosure and the electronic device manufactured thereby, the through holes of the substrate are filled by sequentially performing multiple coating steps to respectively form the first coating and the second coating, and the first coating step and the second coating step are performed using different current densities and/or types of current, so that good through hole filling performance may be provided, thereby reducing the probability of forming voids or gaps within the through holes. Furthermore, the grain size of the first coating formed near the center of the through hole is relatively small, which helps reduce stress caused by mismatches in the thermal expansion coefficients between different materials of layers. In addition, the second coating step may include a plurality of sub-steps to respectively form different portions of the second coating. By changing the current density and coating time in each sub-step of the second coating step, the volume ratio, crystallization density, grain size, and/or crystal orientation of each partial region may be adjusted, and therefore the probability of forming voids within the through hole may be reduced, and stress between layers may be mitigated, thereby lowering the risk of substrate fracture. As described above, the manufacturing method of the present disclosure may improve the signal transmission quality and reliability of the manufactured electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate;
forming a through hole penetrating the substrate;
providing a seed layer, wherein the seed layer extends into the through hole;
performing a first coating step to form a first coating on a surface of the seed layer, wherein the first coating fills a portion of the through hole; and
performing a second coating step to form a second coating on a portion of the surface of the seed layer, wherein the second coating fills another portion of the through hole and is connected to the first coating,
wherein a current density used in the first coating step is greater than a current density used in the second coating step.

2. The manufacturing method of the electronic device according to claim 1, wherein the first coating has two recesses respectively located on opposite sides of the first coating, the substrate has a thickness, and a depth of each of the recesses is greater than or equal to one-fourth of the thickness and less than or equal to one-half of the thickness.

3. The manufacturing method of the electronic device according to claim 1, further comprising performing a first inspection step to inspect a quality of the first coating after performing the first coating step.

4. The manufacturing method of the electronic device according to claim 1, wherein the second coating step comprises a plurality of sub-steps, and different current densities are used in any two of the plurality of sub-steps.

5. The manufacturing method of the electronic device according to claim 4, wherein the plurality of sub-steps comprise a first sub-step and a second sub-step, the first sub-step is performed to form a first portion of the second coating, and then the second sub-step is performed to form a second portion of the second coating, wherein a current density used in the second sub-step is greater than a current density used in the first sub-step.

6. The manufacturing method of the electronic device according to claim 5, wherein a grain size of the first portion is smaller than a grain size of the second portion, and the first portion is located between the first coating and the second portion in a normal direction of the substrate.

7. The manufacturing method of the electronic device according to claim 5, wherein a coating time of the first sub-step is greater than a coating time of the second sub-step.

8. The manufacturing method of the electronic device according to claim 1, wherein a periodically varying current is used in the first coating step, and a direct current is used in the second coating step.

9. The manufacturing method of the electronic device according to claim 1, wherein a grain size of the first coating is smaller than a grain size of the second coating.

10. The manufacturing method of the electronic device according to claim 1, wherein a coating time of the first coating step is greater than a coating time of the second coating step.

11. The manufacturing method of the electronic device according to claim 1, further comprising performing a second inspection step to inspect a quality of the second coating after performing the second coating step.

12. An electronic device, comprising:
a substrate, comprising a through hole penetrating the substrate;
a seed layer disposed on a side wall of the through hole;
a first coating disposed on a surface of the seed layer and filling a portion of the through hole; and
a second coating disposed on a portion of the surface of the seed layer and filling another portion of the through hole, wherein the second coating is connected to the first coating,
wherein a grain size of the first coating is smaller than a grain size of the second coating.

13. The electronic device according to claim 12, wherein the first coating has two recesses respectively located on opposite sides of the first coating, the substrate has a thickness, and a depth of each of the recesses is greater than or equal to one-fourth of the thickness and less than or equal to one-half of the thickness.

14. The electronic device according to claim 12, wherein a volume ratio of the second coating in the through hole is greater than or equal to 11% and less than or equal to 87%.

15. The electronic device according to claim 12, wherein the second coating comprises a first portion and a second portion, a grain size of the first portion is smaller than a grain size of the second portion, and the first portion is located between the first coating and the second portion in a normal direction of the substrate.

16. The electronic device according to claim 15, wherein in a cross-sectional view of the electronic device, a first spacing exists between two adjacent grain boundary profiles of the first portion, and a second spacing exists between two adjacent grain boundary profiles of the second portion, wherein the first spacing is less than the second spacing.

17. The electronic device according to claim 16, wherein a ratio of the first spacing to a minimum diameter of the through hole is greater than or equal to 0.08 and less than or equal to 0.13, and a ratio of the second spacing to the minimum diameter of the through hole is greater than or equal to 0.07 and less than or equal to 0.12.

18. The electronic device according to claim 12, wherein in a cross-sectional view of the electronic device, an included angle between an upper surface or a lower surface of the substrate and the side wall of the through hole is greater than or equal to 90 degrees and less than or equal to 100 degrees.

19. The electronic device according to claim 12, wherein a minimum thickness of the first coating is greater than 0.5 micrometers.

20. The electronic device according to claim 12, wherein a minimum thickness of the seed layer is greater than or equal to 0.5 micrometers.
